(19) United States
(12) Patent Application Publication
(10) Pub. No.: US 2026/0162933 A1
(43) Pub. Date: Jun. 11, 2026

(54) MULTI-CHARGED-PARTICLE-BEAM WRITING METHOD AND MULTI-CHARGED-PARTICLE-BEAM WRITING APPARATUS

(71) Applicant: NuFlare Technology, Inc., Yokohama-shi (JP)

(72) Inventors: Hayato KIMURA, Sunto-gun (JP); Takuya MATSUKAWA, Yokohama-shi (JP); Kei HASEGAWA, Yokohama-shi (JP)

(73) Assignee: NuFlare Technology, Inc., Yokohama-shi (JP)

(21) Appl. No.: 19/382,388

(22) Filed: Nov. 7, 2025

(30) Foreign Application Priority Data
Dec. 11, 2024 (JP) 2024-216911

(51) Int. Cl. H01J 37/304; H01J 37/20; H01J 37/21; H01J 37/317; H01L 21/263

(52) U.S. Cl. CPC H01J 37/3045; H01J 37/20; H01J 37/21; H01J 37/3177; H10P 34/40; H01J 2237/20285

(57) ABSTRACT

In one embodiment, a writing method includes calculating irradiation times for each shot of individual beams of multiple charged particle beams, setting, based on the calculated irradiation times, an ON or OFF state of each individual beam at each irradiation step in a shot cycle comprising a plurality of irradiation steps, extracting a number of beams set in the ON state at a longest irradiation step in each shot with the multiple charged particle beams, determining, based on the extracted number of beams, whether to change the shot cycle, and sequentially applying, based on the determining, the beams corresponding to the irradiation times of the plurality of irradiation steps to a substrate placed on a stage to write a pattern on the substrate, while performing tracking control such that an irradiation region irradiated with the multiple charged particle beams follows movement of the stage.

### CROSS REFERENCE TO RELATED APPLICATION

This application is based upon and claims benefit of priority from the Japanese Patent Application No. 2024-216911, filed on Dec. 11, 2024, the entire contents of which are incorporated herein by reference.

### FIELD

The present invention relates to a multi-charged-particle-beam writing method and a multi-charged-particle-beam writing apparatus.

### BACKGROUND

As LSI circuits are increasing in density, the required linewidths of circuits included in semiconductor devices become finer year by year. To form a desired circuit pattern on a semiconductor device, a method is employed in which a high-precision original pattern formed on quartz is transferred to a wafer in a reduced manner by using a reduced-projection exposure apparatus. High-precision original patterns are written by an electron beam writing apparatus, and so-called electron beam lithography technique is used.

A writing apparatus using multiple beams enables irradiation with a large number of beams at once as compared with writing with a single electron beam, and thereby significantly improve throughput. Examples of such multi-beam writing apparatuses include a multi-beam writing apparatus using a blanking aperture array substrate (blanking plate). In such a multi-beam writing apparatus, for example, an electron beam emitted from a single electron gun passes through a shaping aperture array substrate having multiple apertures, thus forming multiple beams (multiple electron beams). The blanking aperture array substrate is disposed downstream of the shaping aperture array substrate. The blanking aperture array substrate includes pairs of electrodes for individually deflecting the beams, and has an aperture for beam passage between each pair of electrodes. One of the paired electrodes (blanker) is held at ground potential, and the other electrode is switched between the ground potential and a potential other than the ground potential, thus achieving blanking deflection of an electron beam that is to pass through the blanker. The multi-beam writing apparatus includes an optical column configured such that an electron beam deflected by the blanker is blocked and switched to an OFF state and an electron beam that is not deflected is applied as an ON-state beam to a sample.

In writing with multiple beams, the total beam current used for exposure can be increased. An increase in total beam current may cause a deterioration in writing accuracy due to the Coulomb effect. For example, beam position displacement or defocus may occur on the surface of a sample due to a repulsive force between electrons. The magnitude of the Coulomb effect depends on the ON-state beam current, or the number of beams (ON-state beams) that are controlled to the ON state through the blanking aperture array substrate and thus reach the surface of a sample.

When the number of ON-state beams changes significantly, the influence of the Coulomb effect also changes greatly. This results in larger beam-position variations, leading to a deterioration in writing accuracy.

### BRIEF DESCRIPTION OF THE DRAWINGS

FIG. 1 is a schematic diagram illustrating the configuration of a writing apparatus according to an embodiment of the present invention;

FIG. 2 is a plan view of a shaping aperture array substrate;

FIG. 3 is a diagram illustrating an example writing operation;

FIG. 4 is a diagram illustrating an example irradiation region for multiple beams and example writing target pixels;

FIG. 5 is a diagram illustrating an example multi-beam writing method;

FIG. 6 is a schematic diagram illustrating the configuration of a blanking aperture array substrate;

FIG. 7 is a diagram illustrating the configurations of input/output (I/O) circuits and the configuration of a cell array circuit;

FIG. 8 is a schematic diagram illustrating the configuration of an individual blanking mechanism;

FIG. 9 is a diagram illustrating example irradiation steps in one shot cycle;

FIG. 10 is a diagram illustrating example beam ON timing.

FIG. 11 is a diagram illustrating an example of addition of a longest irradiation step;

FIG. 12 is a diagram illustrating examples of division of ON-state beams;

FIG. 13 is a diagram illustrating example skip of the longest irradiation step;

FIG. 14 is a flowchart explaining a writing method;

FIGS. 15A and 15B are diagrams illustrating example correction of irradiation-time control data;

FIG. 16 is a graph showing example control of a stage speed;

FIG. 17 is a graph showing example control of a stage speed; and

FIG. 18 is a graph showing example control of a stage speed.

### DETAILED DESCRIPTION

In one embodiment, a multi-charged-particle-beam writing method includes calculating irradiation times for each shot of individual beams of multiple charged particle beams, setting, based on the calculated irradiation times, an ON or OFF state of each individual beam at each irradiation step in a shot cycle comprising a plurality of irradiation steps, extracting a number of beams set in the ON state at a longest irradiation step with the longest irradiation time of the plurality of irradiation steps in each shot with the multiple charged particle beams, determining, based on the extracted number of beams, whether to change the shot cycle, and sequentially applying, based on the determining, the beams corresponding to the irradiation times of the plurality of irradiation steps to a substrate placed on a stage to write a pattern on the substrate, while performing tracking control such that an irradiation region irradiated with the multiple charged particle beams follows movement of the stage.

In the following embodiments, a configuration using an electron beam as an example of a charged particle beam will be described. However, the charged particle beam is not limited to an electron beam, and may also be a beam using charged particles such as an ion beam.

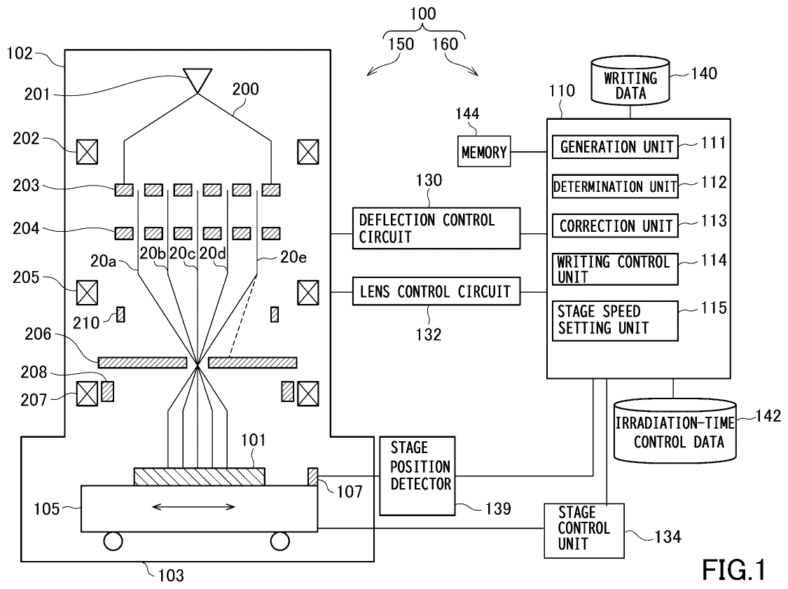

FIG. 1 is a schematic diagram illustrating the configuration of a writing apparatus according to an embodiment. As illustrated in FIG. 1, a writing apparatus 100 includes a writing unit 150 and a controller 160. The writing apparatus 100 is an example of a multi-charged-particle-beam writing apparatus. The writing unit 150 includes an electron optical column 102 and a writing chamber 103. The electron optical column 102 contains, for example, an electron source 201, an illumination lens 202, a shaping aperture array substrate 203, a blanking aperture array substrate 204, a demagnification lens 205, a collective blanking deflector 210, a limiting aperture member 206, an objective lens 207, and a deflector 208. The electron optical column 102 further contains a focus correction lens (not illustrated) that dynamically corrects the focus of a beam during writing.

The writing chamber 103 contains an XY stage 105. A writing target substrate 101 is placed on the XY stage 105. The substrate 101 has an upper surface coated with resist that is to be exposed to electron beams. The substrate 101 is, for example, a substrate (mask blank) to be processed as an exposure mask that is used to fabricate a semiconductor device or a semiconductor substrate (silicon wafer) to be processed as a semiconductor device. The XY stage 105 has thereon a mirror 107 for measuring the position of the stage.

The controller 160 includes a control computer 110, a deflection control circuit 130, a lens control circuit 132, a stage control unit 134, a stage position detector 139, and storage units 140 and 142. The storage unit 140 stores externally input writing data. The writing data typically includes defined information on multiple figure patterns to be written. Specifically, for example, a figure code, coordinates, and dimensions are defined for each figure pattern. The storage unit 142 stores irradiation-time control data, which will be described later.

The control computer 110 includes a generation unit 111, a determination unit 112, a correction unit 113, a writing control unit 114, and a stage speed setting unit 115. These units of the control computer 110 may be implemented by hardware such as electric circuitry or software such as a program that causes the control computer 110 to achieve functions of the units, or may be implemented by a combination of hardware and software.

The stage position detector 139 emits laser light and receives reflected light from the mirror 107 to detect the position of the XY stage 105 based on the principle of laser interferometry.

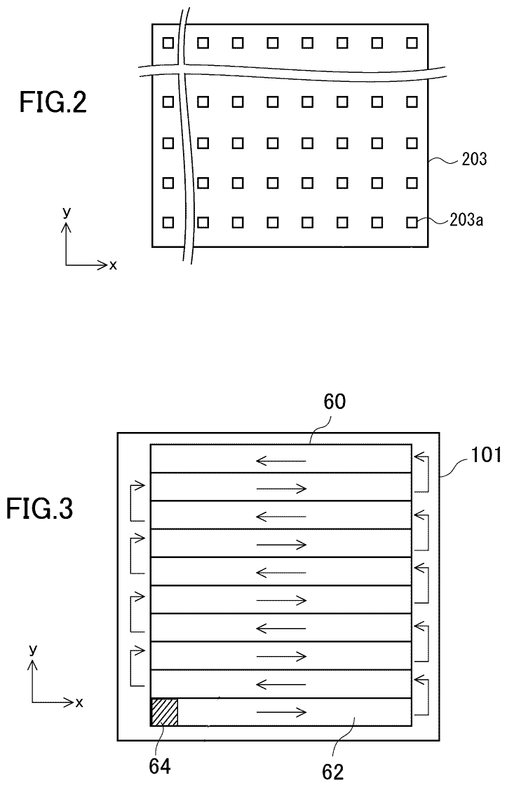

FIG. 2 is a conceptual diagram illustrating the configuration of the shaping aperture array substrate 203. As illustrated in FIG. 2, the shaping aperture array substrate 203 has multiple apertures 203a arrayed in a longitudinal direction (y direction) of the substrate and in a lateral direction (x direction) thereof at a predetermined array pitch. For example, the apertures 203a are rectangular or circular and have the same (substantially the same) dimensions and shape.

An electron beam 200 emitted from the electron source 201 (emitter) is applied substantially perpendicularly to the entire shaping aperture array substrate 203 through the illumination lens 202. The electron beam 200 illuminates a region including the multiple apertures 203a. A portion of the electron beam 200 passes through the multiple apertures 203a of the shaping aperture array substrate 203, whereas the rest of the beam is blocked by the shaping aperture array substrate 203. The electron beam 200 passes through the multiple apertures 203a, thus forming multiple beams including individual beams 20a to 20e.

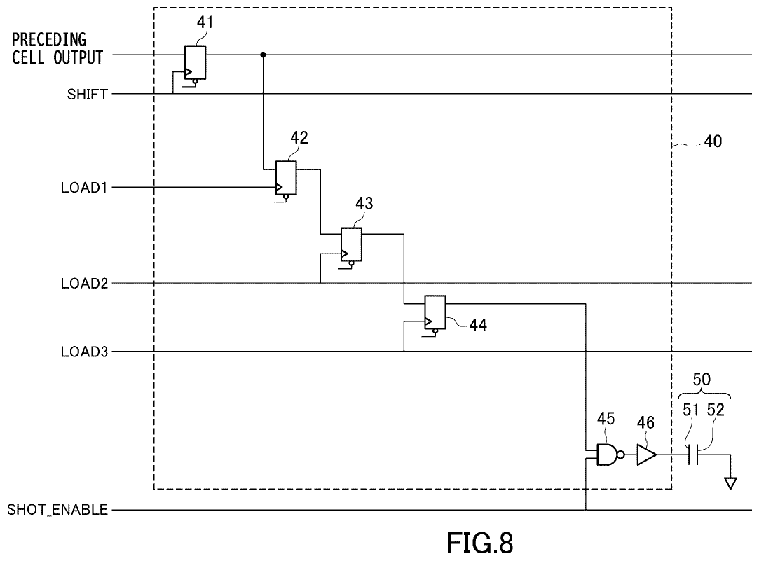

The blanking aperture array substrate 204 has beam passage holes aligned with the respective apertures 203a of the shaping aperture array substrate 203. Each of the passage holes is provided with a blanker 50 including two electrodes 51 and 52 (refer to FIG. 8) paired. One of the electrodes, or the electrode 52, is grounded and held at ground potential, and the other electrode 51 is switched between the ground potential and a potential other than the ground potential, thus switching a beam passing through the passage hole between ON and OFF states for deflection. This enables blanking control.

For the beam ON state, the facing electrodes 51 and 52 of the blanker 50 are controlled at the same potential, so that the blanker 50 does not deflect the beam. For the beam OFF state, the facing electrodes 51 and 52 of the blanker 50 are controlled at different potentials, so that the blanker 50 deflects the beam. Multiple blankers 50 perform blanking deflection on corresponding beams of the multiple beams passing through the apertures 203a of the shaping aperture array substrate 203, thus controlling the corresponding beams to the OFF state.

The multiple beams passing through the blanking aperture array substrate 204 are demagnified by the demagnification lens 205, and travel toward a central aperture of the limiting aperture member 206.

The beam controlled to the beam OFF state is deflected by the blanker 50 and travels along a trajectory outside the aperture of the limiting aperture member 206, and is thus blocked by the limiting aperture member 206. On the other hand, the beam controlled to the beam ON state is not deflected by the blanker 50 and thus passes through the aperture of the limiting aperture member 206. As described above, the blankers 50 are switched between the ON and OFF states for deflection, thus individually controlling the beams to the ON or OFF state.

Furthermore, the collective blanking deflector 210 enables all the multiple beams to be collectively subjected to blanking deflection.

The multiple beams passing through the limiting aperture member 206 are focused by the objective lens 207, thus forming a pattern image at a desired demagnification ratio. The individual beams (all the multiple beams) passing through the limiting aperture member 206 are collectively deflected by the deflector 208 and are applied to desired positions on the substrate 101.

In the case where the XY stage 105 is continuously moving, at least while the substrate 101 is being irradiated with the beams, the deflector 208 performs control such that beam irradiation positions on the substrate 101 follow the movement of the XY stage 105.

For example, writing is performed based on the following writing algorithm. As illustrated in FIG. 3, a writing area 60 of the substrate 101 is virtually divided into stripe regions 62, each of which has a predetermined width and a strip shape and which are arranged in, for example, the y direction. For example, the XY stage 105 is moved and adjusted such that an irradiation region 64, which can be irradiated with the multiple beams at once, is positioned at the left end of the first stripe region 62. Then, writing is started. Moving the XY stage 105 in the −x direction allows writing to proceed in the +x direction relative to the XY stage 105.

At completion of writing in the first stripe region 62, the position of the stage is shifted in the −y direction and is adjusted such that the irradiation region is positioned at the right end of the second stripe region 62. Then, writing is started. Moving the XY stage 105 in, for example, the +x direction allows writing to be performed in the −x direction.

Writing is performed in a zigzag manner such that writing is performed in the third stripe region 62 in the +x direction and such that writing is performed in the fourth stripe region 62 in the −x direction. This manner of writing results in a reduction in writing time. The manner of writing is not limited to the above-described zigzag manner. For writing in the stripe regions 62, writing may be performed in the same direction.

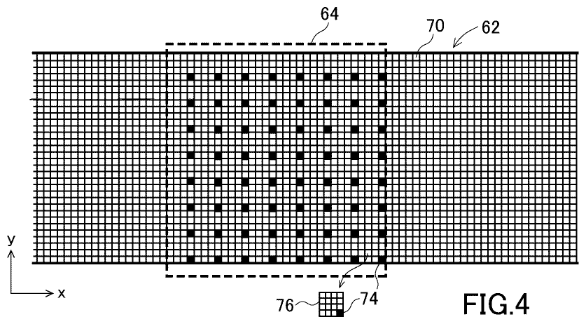

FIG. 4 is a diagram illustrating an example irradiation region for multiple beams and example writing target pixels. In FIG. 4, the stripe region 62 is divided into mesh regions that are arranged in a mesh and each of which corresponds to the size of each of the individual beams constituting the multiple beams, for example. Each mesh region serves as a writing target pixel 70 (unit irradiation region or writing position). The size of the writing target pixel 70 is not limited to the beam size, and may be any size, irrespective of the beam size. For example, the writing target pixel 70 may have a size that is 1/m (where m is an integer of 1 or more) of the beam size.

FIG. 4 illustrates an example in which the writing area of the substrate 101 is divided into stripe regions 62 each having a width that is substantially the same as the dimension in, for example, the y direction, of the irradiation region 64 (writing field), which can be irradiated with the multiple beams at once. The width of the stripe region 62 is not limited to this example.

FIG. 4 illustrates the multiple beams in an array of 8×8. In the irradiation region 64, multiple (in this example, 64) pixels 74 (beam writing positions) that can be irradiated with a single shot of the multiple beams are illustrated. A pitch between the adjacent pixels 74 corresponds to a pitch between the individual beams of the multiple beams. In the example of FIG. 4, one grid 76 is a square region that is defined by four sets of four adjacent pixels 74 and that includes one pixel 74 of the four pixels 74. In the example of FIG. 4, each grid 76 is composed of 4×4 pixels.

FIG. 5 is a diagram illustrating an example multi-beam writing method based on continuous movement. FIG. 5 illustrates grids in which writing is performed with eight beams in the first row in the y direction of the multiple beams for writing in the stripe region 62 illustrated in FIG. 4.

FIG. 5 illustrates an example in which four pixels are subjected to writing (exposure) while the XY stage 105 is moving a distance of, for example, eight beam pitches (8p). While four pixels are being subjected to writing (exposure), the deflector 208 collectively deflects all the multiple beams so that the irradiation region 64 is not shifted relative to the substrate 101 by movement of the XY stage 105. Thus, the irradiation region 64 is caused to follow the movement of the XY stage 105. In other words, tracking control is performed. In the example of FIG. 5, one tracking cycle is implemented by subjecting four pixels to writing (exposure) during movement over a distance of eight beam pitches.

Let T denote a writing time (maximum exposure time) for each pixel. For example, the first pixel from the left of the bottom row in each of the grids of interest is irradiated with a beam of the first shot for a period from time t=0 to time t=T. The XY stage 105 moves in the −x direction by, for example, two beam pitches (2p), for the period from time t=0 to time t=T. The tracking operation continues for this period. At time t=0 in FIG. 5, the grids are irradiated with beams #1 to #8. For the grids at and after time t=T, the positions irradiated with the beam #1 are illustrated for convenience of description. Pixels irradiated with the beam are illustrated by hatching.

At time t=T, the multiple beams are collectively deflected independently of beam deflection for the tracking control while the beam deflection for the tracking control is being continued. Thus, the writing positions of the beams are shifted. In the example of FIG. 5, each writing target pixel is shifted from the first pixel from the left in the bottom row of the grid of interest to the first pixel from the left in the second row from the bottom. The tracking operation continues for this period because the XY stage 105 is moving.

For a period from time t=T to time t=2T, the first pixel from the left in the second row from the bottom of the grid of interest is irradiated with the beam of the second shot. The XY stage 105 moves in the −x direction by two beam pitches for the period from time t=T to time t=2T. The tracking operation continues for this period.

At time t=2T, the deflector 208 collectively deflects the multiple beams, so that each writing target pixel is shifted from the first pixel from the left in the second row from the bottom of the grid of interest to the first pixel from the left in the third row from the bottom. Since the XY stage 105 is moving, the tracking operation continues for this period.

For a period from time t=2T to time t=3T, the first pixel from the left in the third row from the bottom of the grid of interest is irradiated with the beam of the third shot. The XY stage 105 moves in the −x direction by, for example, two beam pitches, for the period from time t=2T to time t=3T. The tracking operation continues for this period.

At time t=3T, the deflector 208 collectively deflects the multiple beams, so that each writing target pixel is shifted from the first pixel from the left in the third row from the bottom of the grid of interest to the first pixel from the left in the fourth row from the bottom. Since the XY stage 105 is moving, the tracking operation continues for this period.

For a period from time t=3T to time t=4T, the first pixel from the left in the fourth row from the bottom of the grid of interest is irradiated with the beam of the fourth shot. The XY stage 105 moves in the −x direction by, for example, two beam pitches, for the period from time t=3T to time t=4T. The tracking operation continues for this period. Writing the pixels in the first column from the left of the grid of interest is finished in the above-described manner.

In the example of FIG. 5, after each beam writing position shifted three times from the initial shot position is irradiated with the corresponding one of the beams, the beam deflection for the tracking control is reset, thereby returning a tracking position to a tracking start position. In other words, the tracking position is moved back in a direction opposite to the direction in which the stage moves. In the example of FIG. 5, at time t=4T, the grid of interest is released from being tracked, and the beam is redirected to a grid of interest located away from the released grid by eight beam pitches in the +x direction. Although FIG. 5 illustrates the beam #1, writing is similarly performed in the grids associated with the other beams.

Writing on the pixels in the first column from the left of each grid is completed. After tracking is reset, the deflector 208 initially deflects the beams in the next tracking cycle such that the beam writing position is adjusted (shifted) to the second pixel from the left in the first row from the bottom of each grid.

For a period from time t=4T to time t=8T, writing is performed on the pixels in the second column from the left of the grid of interest. At time t=8T, the grid of interest is released from being tracked, and the beam is redirected to a grid of interest located away from the released grid by eight beam pitches in the +x direction.

Writing on the pixels in the first and second columns from the left of each grid is completed. After tracking is reset, the deflector 208 initially deflects the beams in the next tracking cycle such that the beam writing position is adjusted (shifted) to the third pixel from the left in the first row from the bottom of each grid.

For a period from time t=8T to time t=12T, writing is performed on the pixels in the third column from the left of the grid of interest. At time t=12T, the grid of interest is released from being tracked, and the beam is redirected to a grid of interest located away from the released grid by eight beam pitches in the +x direction.

Writing on the pixels in the first to third columns from the left of each grid is completed. After tracking is reset, the deflector 208 initially deflects the beams in the next tracking cycle such that the beam writing position is adjusted (shifted) to the fourth pixel from the left in the first row from the bottom of each grid.

As described above, the deflector 208 performs control so that the irradiation region 64 is held at the same position relative to the substrate 101 during the same tracking cycle. In this state, each shot is performed while the pixels are being shifted one by one. At completion of one tracking cycle, the tracking position in the irradiation region 64 is returned such that the first shot position of each beam is adjusted to a position shifted by one pixel. During the next tracking control, each shot is performed while the pixels are being shifted one by one.

Repeating the above-described operation writes a pattern.

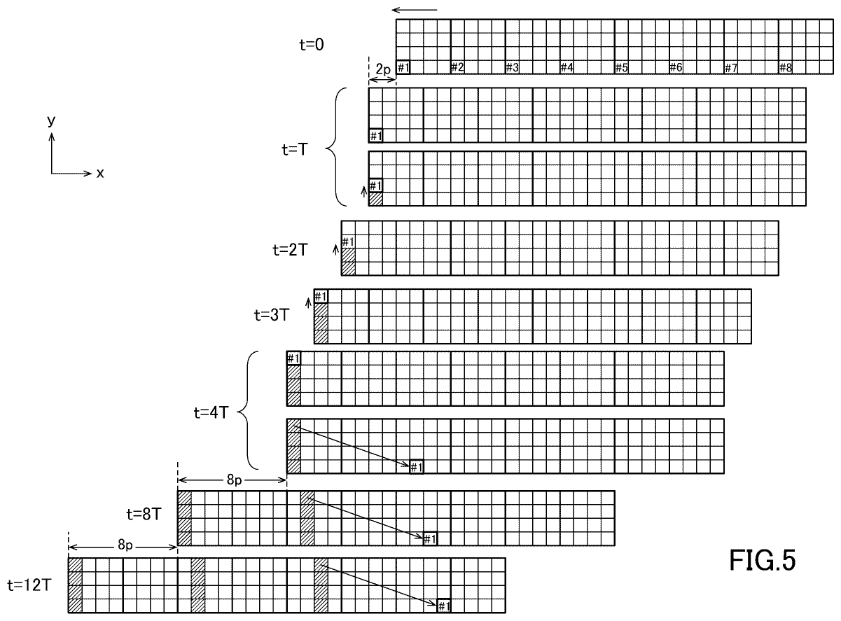

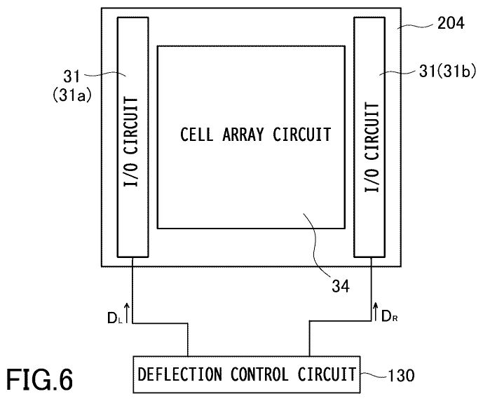

The blanking aperture array substrate 204 for blanking control of each of the multiple beams will now be described. As illustrated in FIG. 6, the blanking aperture array substrate 204 includes I/O circuits 31 (31a, 31b) and a cell array circuit 34. The I/O circuits 31 receive control signals from the deflection control circuit 130.

The cell array circuit 34 is disposed in a central portion of the blanking aperture array substrate 204. The two I/O circuits 31a and 31b are arranged with the cell array circuit 34 therebetween. Two separate data paths D_{L} and D_{R} for the control signals extend from the deflection control circuit 130 to the blanking aperture array substrate 204.

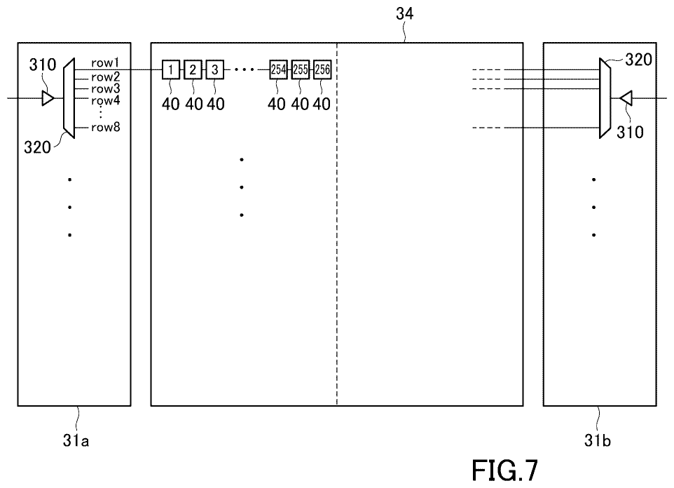

As illustrated in FIG. 7, the cell array circuit 34 includes multiple cells, each serving as an individual blanking mechanism 40. Each individual blanking mechanism 40 corresponds to a single blanker 50. Each I/O circuit 31 converts the control signals received from the deflection control circuit 130 into beam ON/OFF signals and then outputs the signals to the cell array circuit 34. For example, the I/O circuit 31a outputs the beam ON/OFF signals to the individual blanking mechanisms 40 arranged in one half of the cell array circuit 34, and the I/O circuit 31b outputs the beam ON/OFF signals to the individual blanking mechanisms 40 arranged in the other half thereof.

Each I/O circuit 31 includes multiple selectors 320 (demultiplexers). Each selector 320 receives, via an amplifier 310, irradiation-time control data that defines an irradiation time for each beam shot, and outputs the beam ON/OFF signals through the corresponding output lines. Each output line is connected in series with the multiple individual blanking mechanisms 40.

For example, the selector 320 includes eight output lines row1 to row 8. Each output line is connected to 256 individual blanking mechanisms 40. The I/O circuits 31a and 31b each include 64 selectors 320. Such a configuration allows the beam ON/OFF signals to be transferred to 512×512 individual blanking mechanisms 40 in the cell array circuit 34.

The arrangement of the individual blanking mechanisms 40 to which the I/O circuit 31a outputs the beam ON/OFF signals and the arrangement of the individual blanking mechanism 40 to which the I/O circuit 31b outputs the beam ON/OFF signals are not limited to those in FIG. 7. For example, the output lines extending from the I/O circuit 31a and the output lines extending from the I/O circuit 31b may be arranged alternately. Alternatively, the individual blanking mechanisms 40 to which the I/O circuit 31a outputs the beam ON/OFF signals and the individual blanking mechanisms 40 to which the I/O circuit 31b outputs the beam ON/OFF signals may be arranged alternately.

As illustrated in FIG. 8, each individual blanking mechanism 40 includes a shift register 41, a pre-buffer 42, a buffer 43, a data register 44, a NAND circuit 45, and an amplifier 46. The shift register 41 transfers, in response to a clock signal (SHIFT), data output from the shift register of the previous cell to the shift register of the subsequent cell.

The pre-buffer 42 stores, in response to a clock signal (LOAD1), a beam ON/OFF signal for the cell that is output from the shift register 41.

The buffer 43 captures and holds, in response to a clock signal (LOAD2), a value output from the pre-buffer 42.

The data register 44 captures and holds, in response to a clock signal (LOAD3), a value output from the buffer 43.

The NAND circuit 45 receives an output signal of the data register 44 and a shot enable signal (SHOT_ENABLE). An output signal of the NAND circuit 45 is applied to the electrode 51 of the blanker 50 via the amplifier 46 (driver amplifier).

When both the output signal of the data register 44 and the shot enable signal are at a level “High”, the output of the NAND circuit 45 goes to a level “Low”. This causes the electrode 51 and the electrode 52 to be at the same potential. Thus, the blanker 50 does not deflect a beam, so that the beam is in the ON state. When at least either one of the output signal of the data register 44 and the shot enable signal is at the level “Low”, the output of the NAND circuit 45 goes to the level “High”. This causes the electrode 51 and the electrode 52 to be at different potentials. Thus, the blanker 50 deflects a beam, so that the beam is in the OFF state.

The shot enable signal is input to each of the NAND circuits 45 of all the individual blanking mechanisms 40. Setting the shot enable signal to the level “Low” allows all the beams to enter the OFF state.

While the shot enable signal is maintained at the level “High”, the beam is switched between the ON and OFF states in response to an output of the data register 44. Specifically, when the irradiation-time control data is 1 (“High”), the beam ON/OFF signal serves as an ON signal. When the irradiation-time control data is 0 (“Low”), the beam ON/OFF signal serves as an OFF signal.

In multi-beam writing, each beam is in the ON state only for a desired irradiation time in one shot cycle and is in the OFF state for the remaining time in the shot cycle. For example, a gradation value N is calculated by dividing an irradiation time by a quantization unit Δ. The quantization unit Δ can be variously set and may be defined as 1 ns, for example. The gradation value N is converted into an n-digit binary value, which serves as irradiation-time control data.

For example, when N=50 (50=2⁵+2⁴+2¹) is converted into a 6-digit binary value, irradiation-time control data is “110010”. Similarly, when N=30, irradiation-time control data is “011110”.

The first digit from the right (least significant bit) in irradiation-time control data represents an irradiation time of 1Δ. The second digit from the right in the irradiation-time control data represents an irradiation time of 2Δ. The third digit from the right in the irradiation-time control data represents an irradiation time of 4Δ. The fourth digit from the right in the irradiation-time control data represents an irradiation time of 8Δ. The fifth digit from the right in the irradiation-time control data represents an irradiation time of 16Δ. The sixth digit from the right (most significant bit) in the irradiation-time control data represents an irradiation time of 32Δ.

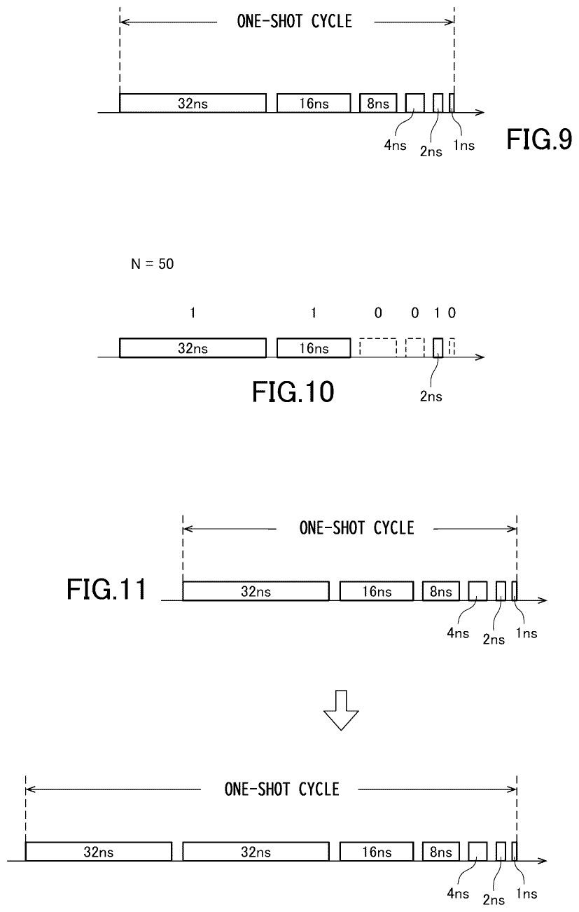

One shot cycle is divided into irradiation steps equal in number to the digits (bits) of irradiation-time control data. Each irradiation step has an irradiation time based on the position of the corresponding digit. For example, when the irradiation steps are performed in order from the highest-order digit and Δ=1 ns, the first irradiation step has an irradiation time of 32 ns, as illustrated in FIG. 9. The second irradiation step has an irradiation time of 16 ns. The third irradiation step has an irradiation time of 8 ns. The fourth irradiation step has an irradiation time of 4 ns. The fifth irradiation step has an irradiation time of 2 ns. The sixth irradiation step has an irradiation time of 1 ns.

For N=50, the irradiation-time control data is “110010”. As illustrated in FIG. 10, the beams are in the ON state at the first (32 ns), second (16 ns), and fifth (2 ns) irradiation steps and are in the OFF state at the third, fourth, and sixth irradiation steps.

The irradiation steps may be performed in order from the lowest-order digit (the irradiation step having the shortest irradiation time).

As described above by way of example, in multi-beam writing, each shot cycle is divided into irradiation steps, and each beam is switched between the ON and OFF states at each irradiation step to provide a desired irradiation time. For example, the irradiation steps have different irradiation times, each of which is proportional to a power of 2.

In multi-beam writing, a significant change in the number of ON-state beams between shots results in a significant change in influence of the Coulomb effect. This may lead to a deterioration in writing accuracy.

The present embodiment focuses on an irradiation step (longest irradiation step) having the longest irradiation time in each shot cycle. When the number of ON-state beams at the longest irradiation step is greater than a first threshold Th1, the ON-state beams are divided into two groups, a longest irradiation step is added to the shot cycle, the ON-state beams of one of the two groups are applied at one of the longest irradiation steps, and the ON-state beams of the other group are applied at the other longest irradiation step. Thus, the number of ON-state beams at each longest irradiation step can fall within a predetermined range. This can reduce a change in the number of ON-state beams between the shots.

When the longest irradiation step is performed two times, the number of irradiation steps included in one shot cycle increases by one, as illustrated in FIG. 11. Therefore, the number of bits of irradiation-time control data also increases by one. The most significant bit and the second most significant bit correspond to ON/OFF at the longest irradiation steps. FIG. 11 illustrates an example in which the seventh digit from the right (most significant bit) and the sixth digit from the right (second most significant bit) in irradiation-time control data each represent an irradiation time of 32Δ. When Δ=1 ns, 32Δ represents 32 ns.

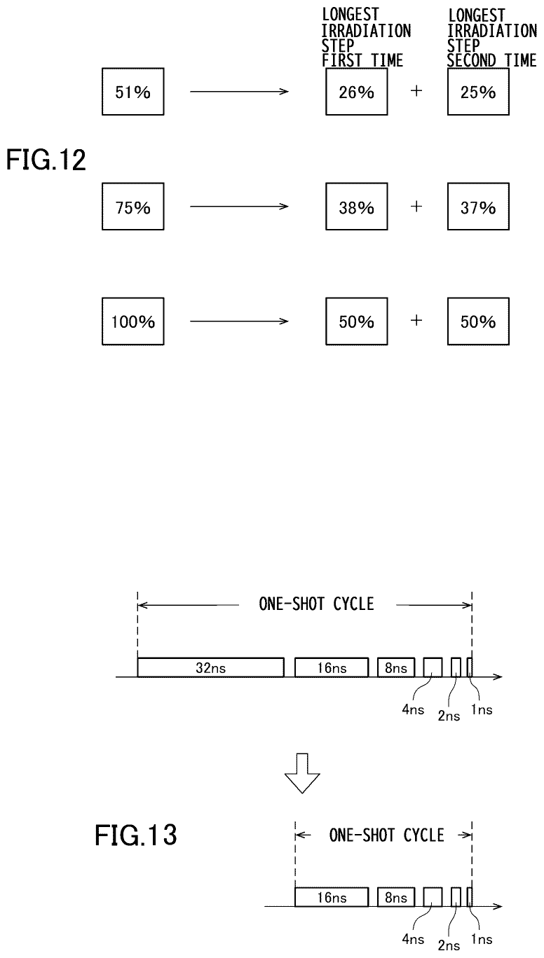

The first threshold Th1 may be, but not particularly limited to, 50% of the total number of multiple beams, for example. As illustrated in FIG. 12, when ON-state beams at the longest irradiation step correspond to 51% of the total number of beams, the beams corresponding to 51% are divided into a group of beams corresponding to 26% and a group of beams corresponding to 25%. The beams corresponding to 26% are set to the ON state at the first longest irradiation step. The beams corresponding to 25% are set to the ON state at the second longest irradiation step.

When ON-state beams at the longest irradiation step correspond to 75% of the total number of beams, the beams corresponding to 75% are divided into a group of beams corresponding to 38% and a group of beams corresponding to 37%. The beams corresponding to 38% are set to the ON state at the first longest irradiation step. The beams corresponding to 37% are set to the ON state at the second longest irradiation step.

When ON-state beams at the longest irradiation step correspond to 100% of the total number of beams, the beams corresponding to 100% are divided into a group of beams corresponding to 50% and a group of beams corresponding to 50%. The beams corresponding to 50% are set to the ON state at the first longest irradiation step. The beams corresponding to the remaining 50% are set to the ON state at the second longest irradiation step.

The present embodiment focuses on the number of ON-state beams at the longest irradiation step in each of multiple shots included in one tracking cycle. When the number of ON-state beams is less than a second threshold Th2 (Th2<Th1), irradiation at this longest irradiation step is not performed (or skipped) during the same tracking cycle. Data on the skipped irradiation is stored in a memory 144. An additional tracking cycle to start after tracking is reset is made. In the additional tracking cycle, irradiation corresponding to the longest irradiation step with the number of ON-state beams less than the second threshold Th2 is performed.

When the longest irradiation step is not performed, the number of irradiation steps included in one shot cycle decreases by one, as illustrated in FIG. 13. Therefore, the number of bits of irradiation-time control data also decreases by one.

The second threshold Th2 may be, but not particularly limited to, 25% of the total number of multiple beams, for example. For example, when ON-state beams at the longest irradiation step correspond to 20% of the total number of beams, irradiation at this longest irradiation step is not performed during the same tracking cycle. The irradiation is performed in the additional tracking cycle.

In the additional tracking cycle, which uses a small number of ON-state beams, the influence of the Coulomb effect differs from that in the case where the number of ON-state beams is equal to or greater than Th2 and less than or equal to Th1. For this reason, the beams are adjusted using an optical system including the focus correction lens so that, for example, beam-position variations are substantially the same as when the number of ON-state beams is greater than or equal to Th2 and less than or equal to Th1. For example, in the additional tracking cycle, focus correction is performed using the focus correction lens so that beam-position variations are substantially the same as when ON-state beams correspond to 38% of the total number of beams.

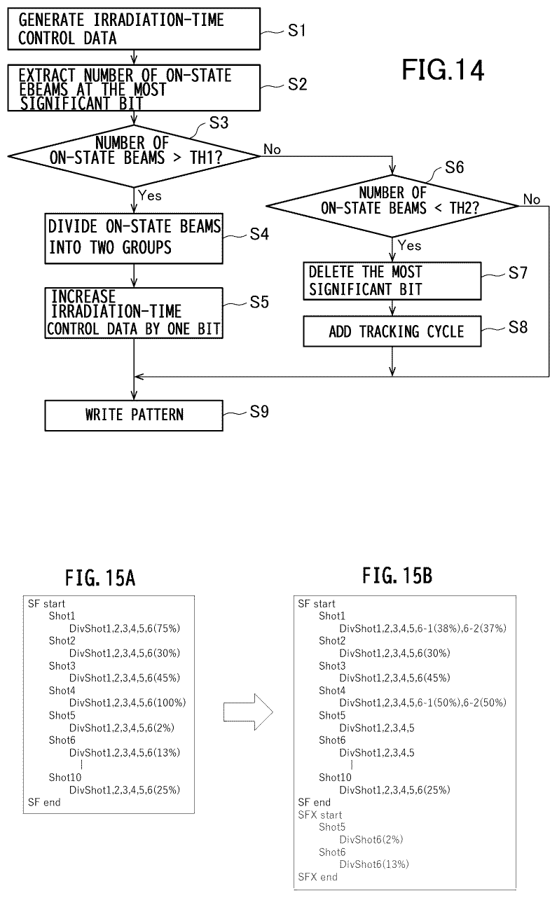

Processes of the units of the control computer 110 will now be described with reference to a flowchart illustrated in FIG. 14.

The generation unit 111 virtually divides a writing area on the substrate 101 into mesh regions. The mesh regions each have substantially the same size as that of one beam, for example. Each mesh region serves as a pixel (unit irradiation region). The generation unit 111 reads writing data from the storage unit 140 and calculates a pattern area density ρ of each of the pixels by using a pattern defined in the writing data.

The generation unit 111 multiplies the pattern area density ρ by a reference dose and a correction factor for, for example, proximity effect correction, to calculate the dose of a beam to be applied to each pixel. The generation unit 111 divides the dose by a current density to calculate an irradiation time.

The generation unit 111 distributes the irradiation time to multiple irradiation steps to generate irradiation-time control data (shot data) (step S1). For example, the generation unit 111 divides the irradiation time by a quantization unit to calculate a gradation value (irradiation time represented as an integer). For the example of FIG. 9, the generation unit 111 obtains, as irradiation-time control data, a sequence of ON/OFF flags corresponding to a sequence (2⁵, 2⁴, 2³, 2², 2¹, 2⁰) and sets the ON/OFF state of the beam at each irradiation step.

The determination unit 112 extracts, for each shot cycle, the number of ON-state beams at the most significant bit (longest irradiation step) in the irradiation-time control data associated with the individual beams of the multiple beams (step S2). The determination unit 112 determines, based on the extracted number of ON-state beams, whether to change the shot cycle as follows. If the number of ON-state beams is greater than the first threshold Th1 (Yes in step S3), the determination unit 112 divides the ON-state beams at the longest irradiation step into two groups, a first group and a second group (step S4). The two groups have (substantially) the same number of beams.

The correction unit 113 corrects the irradiation-time control data to increase the number of bits of the control data by one and assigns the longest irradiation step to the upper two bits (the most significant bit and the second most significant bit) (step S5). For example, for the first group of beams, the correction unit 113 sets the most significant bit to “1” and the second most significant bit to “0”. For the second group of beams, the correction unit 113 sets the most significant bit to “0” and the second most significant bit to “1”.

If the number of ON-state beams is less than the first threshold Th1 and is less than the second threshold Th2 (No in step S3, Yes in step S6), the correction unit 113 corrects the irradiation-time control data such that the most significant bit corresponding to the longest irradiation step is assigned to an additional tracking cycle, not to the same tracking cycle (step S7). If the number of ON-state beams is less than the first threshold Th1 and is greater than or equal to the second threshold Th2 (No in step S3, No in step S6), the irradiation-time control data remains uncorrected.

FIG. 15A illustrates irradiation-time control data to be corrected by the correction unit 113. FIG. 15B illustrates corrected irradiation-time control data. One tracking cycle is between “SF start” and “SF end”. In the example of FIG. 15A, one tracking cycle includes ten shots (Shot1 to 10). In other words, ten pixels are exposed in one tracking cycle. One shot (one shot cycle) includes six irradiation steps (DivShot1 to DivShot6).

For example, FIG. 15A shows that the longest irradiation step DivShot6 in Shot1 uses ON-state beams corresponding to 75% of all the multiple beams and the longest irradiation step DivShot6 in Shot6 uses ON-state beams corresponding to 13% of all the multiple beams.

In the example of FIG. 15A, the number of ON-state beams at the longest irradiation step DivShot6 in each of Shot1 and Shot4 is greater than the first threshold Th1 (e.g., 50%). Therefore, the ON-state beams are divided into two groups. As illustrated in FIG. 15B, which illustrates the corrected irradiation-time control data, one bit is added for each of Shot1 and Shot4, and the upper two bits are assigned to longest irradiation steps (DivShot6-1, DivShot6-2). FIG. 15B shows that the longest irradiation step DivShot6-1 in Shot1 uses ON-state beams corresponding to 38% of all the multiple beams and the longest irradiation step DivShot6-2 uses ON-state beams corresponding to 37% of all the multiple beams.

Similarly, as illustrated in FIG. 15B, the longest irradiation step DivShot6-1 in Shot4 uses ON-state beams corresponding to 50% of all the multiple beams and the longest irradiation step DivShot6-2 uses ON-state beams corresponding to the remaining 50%.

In the example of FIG. 15A, the number of ON-state beams at the longest irradiation step DivShot6 in each of Shot5 and Shot6 is less than the second threshold Th2 (e.g., 25%). Therefore, as illustrated in FIG. 15B, the irradiation-time control data is corrected such that the most significant bit in each of Shot5 and Shot6 is skipped and an additional tracking cycle is made to perform the irradiation steps corresponding to the skipped most significant bits in the additional tracking cycle (between SFX start and SFX end).

The writing control unit 114 transfers the corrected irradiation-time control data to the deflection control circuit 130. The deflection control circuit 130 switches each of the multiple beams between the ON and OFF states based on the irradiation-time control data to control an exposure time for each pixel on the substrate 101, thus writing a pattern (step S9).

In the pattern writing process, in each of Shot1 and Shot4, irradiation at the longest irradiation step is performed two times. In each of Shot5 and Shot6, irradiation at the longest irradiation step is skipped. Data on the skipped irradiation is stored in the memory 144. The skipped irradiation is performed in the additional tracking cycle. The same pixels as those exposed at DivShot1 to DivShot5 in Shot5 are exposed at DivShot6 in Shot5 of the additional tracking cycle.

When tracking is reset and the additional tracking cycle starts, the lens control circuit 132 controls the focus correction lens to correct the foci of the multiple beams. When the additional tracking cycle ends and tracking is reset, the lens control circuit 132 controls the focus correction lens to restore the foci of the multiple beams.

According to the present embodiment, as described above, a change in the number of ON-state beams is reduced. This reduces a change in influence of the Coulomb effect, thus reducing beam-position variations. This leads to improved writing accuracy.

In the above embodiment, the XY stage 105 moves at a constant reference speed. If the number of times of two-time irradiation resulting from division of the longest irradiation step is increased and writing takes longer time, the amount of deflection by the deflector 208 may exceed its upper limit. Tracking may fail to be performed.

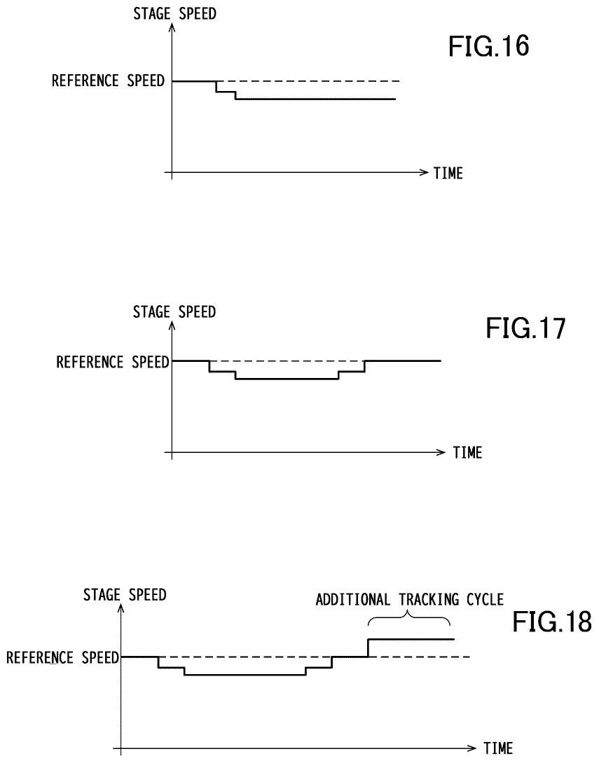

For this reason, as illustrated in FIG. 16, the speed of the XY stage 105 may be reduced each time two-time irradiation resulting from division of the longest irradiation step is performed the predetermined number of times. The stage speed setting unit 115 transmits a set value for the stage speed to the stage control unit 134. The stage control unit 134 reduces the speed of the XY stage 105 based on the received set value. The speed may be increased or reduced in a step-by-step manner or may be gradually increased or reduced such that the speed changes linearly or in a curve, such as a sine curve.

If the number of ON-state beams is less than the second threshold Th2 and the longest irradiation step (the most significant bit) in the shot cycle is skipped, the speed of the XY stage 105 may be increased so as not to exceed the reference speed, as illustrated in FIG. 17. For example, when tracking is reset and the additional tracking cycle starts, the speed of the XY stage 105 may be increased.

Since the additional tracking cycle includes only irradiation corresponding to the longest irradiation step with a small number of ON-state beams, the speed of the XY stage 105 may be increased such that the XY stage 105 moves at a speed higher than the reference speed, as illustrated in FIG. 18.

As described in the above embodiment, when the number of ON-state beams at the longest irradiation step is greater than the first threshold Th1, the ON-state beams are divided (separated) into a first group and a second group, two longest irradiation steps are performed, the ON-state beams of the first group are applied at one of the two longest irradiation steps, and the ON-state beams of the second group are applied at the other longest irradiation step. The ON-state beams may be divided into M (M is an integer of 3 or more) groups, and M longest irradiation steps may be performed.

In the above embodiment, after generation of writing data, the correction unit 113 changes a shot cycle (or adds or skips the longest irradiation step) and makes an additional tracking cycle. The stage control unit 134 controls the stage speed based on the result of operation by the correction unit 113. When writing data is generated, irradiation-time control data based on the number of ON-state beams at the longest irradiation step and a stage speed profile may be generated.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A multi-charged-particle-beam writing method comprising:
calculating irradiation times for each shot of individual beams of multiple charged particle beams;
setting, based on the calculated irradiation times, an ON or OFF state of each individual beam at each irradiation step in a shot cycle comprising a plurality of irradiation steps;
extracting a number of beams set in the ON state at a longest irradiation step with the longest irradiation time of the plurality of irradiation steps in each shot with the multiple charged particle beams;
determining, based on the extracted number of beams, whether to change the shot cycle; and
sequentially applying, based on the determining, the beams corresponding to the irradiation times of the plurality of irradiation steps to a substrate placed on a stage to write a pattern on the substrate, while performing tracking control such that an irradiation region irradiated with the multiple charged particle beams follows movement of the stage.

2. The multi-charged-particle-beam writing method according to claim 1, further comprising, when the extracted number of beams exceeds a first threshold, dividing the beams set in the ON state at the longest irradiation step into a first group and a second group, adding another longest irradiation step to the shot cycle, setting the beams of the first group to the ON state at one of the longest irradiation steps, and setting the beams of the second group to the ON state at the other longest irradiation step.

3. The multi-charged-particle-beam writing method according to claim 1, further comprising, when the extracted number of beams is less than a second threshold, skipping the longest irradiation step in the shot cycle, and, after resetting the tracking control, irradiating the substrate with the beams corresponding to the irradiation time associated with the skipped longest irradiation step.

4. The multi-charged-particle-beam writing method according to claim 3, further comprising correcting a focus of the multiple charged particle beams when resetting the tracking control.

5. The multi-charged-particle-beam writing method according to claim 1, further comprising accelerating or decelerating the stage during the tracking control or after resetting the tracking control.

6. The multi-charged-particle-beam writing method according to claim 5, further comprising decelerating the stage before performing the shot with the added longest irradiation step, and accelerating the stage after completion of the longest irradiation step.

7. A multi-charged-particle-beam writing apparatus comprising:
a generation unit configured to calculate, for each shot of individual beams of multiple charged particle beams, irradiation times for shot cycles comprising a plurality of irradiation steps, and generate irradiation-time control data by setting an ON or OFF state of each of the individual beams at each of the irradiation steps in the shot cycles based on the calculated irradiation times;
a determination unit configured to extract the number of beams set in the ON state at a longest irradiation step with the longest irradiation time of the plurality of irradiation steps in each of the shot cycles with the multiple charged particle beams and determine, based on the extracted number of beams, whether to change the shot cycle; and
a writing unit configured to write a pattern on a substrate by sequentially applying, based on a determination by the determination unit, the beams corresponding to the irradiation times associated with the plurality of irradiation steps to the substrate.
